(19) United States
(12) Patent Application Publication
(10) Pub. No.: US 2010/0117230 A1
(43) Pub. Date: May 13, 2010

(54) Flip Chip Interconnection Structure Having Void-Free Fine Pitch and Method Thereof

(75) Inventors: Rajendra D. Pendse, Fremont, CA (US); Stephen A. Murphy, San Jose, CA (US)

Correspondence Address: Robert D. Atkins, 605 W. Knox Road, Suite 104, Tempe, AZ, 85284, US

(73) Assignee: STATS CHIPPAC, LTD., Singapore (SG)

(21) Appl. No.: 12/688,124

(22) Filed: Jan. 15, 2010

Related U.S. Application Data
(63) Continuation of application No. 12/062,403, filed on Apr. 3, 2008.

(51) Int. Cl. H01L 23/48; H01L 21/00

(52) U.S. Cl. 257/738; 438/108; 257/778; 257/E23.141; 257/E21.001

(57) ABSTRACT

A semiconductor device is made by providing a semiconductor die having a contact pad, forming a circular solder bump on the contact pad, providing a substrate having a trace line, disposing a non-circular solder resist opening over the trace line, placing the solder bump in proximity to the trace line, and reflowing the circular solder bump to metallurgically connect the circular solder bump to the trace line. The circular solder bump contacts less than an entire perimeter of the non-circular solder resist opening which creates one or more vents in areas where the circular solder bump is discontinuous with the non-circular solder resist opening. The non-circular solder resist opening can be a rectangle, triangle, ellipse, oval, star, and tear-drop. An underfill material is deposited under the first substrate. The underfill material penetrates through the vents to fill an area under the solder bump.

### CLAIM TO DOMESTIC PRIORITY

The present application is a continuation of U.S. patent application Ser. No. 12/062,403, filed Apr. 3, 2008, and claims priority to the foregoing parent application pursuant to 35 U.S.C. §120.

### FIELD OF THE INVENTION

The present invention relates in general to semiconductor devices and, more particularly, to a flip chip interconnect structure having a fine pitch and void free construction and underfill.

### BACKGROUND OF THE INVENTION

Semiconductor devices are found in many products in the fields of entertainment, communications, networks, computers, and household markets. Semiconductor devices are also found in military, aviation, automotive, industrial controllers, and office equipment. The semiconductor devices perform a variety of electrical functions necessary for each of these applications.

The manufacture of semiconductor devices involves formation of a wafer having a plurality of die. Each semiconductor die contains hundreds or thousands of transistors and other active and passive devices performing a variety of electrical functions. For a given wafer, each die from the wafer typically performs the same electrical function. Front-end manufacturing generally refers to formation of the semiconductor devices on the wafer. The finished wafer has an active side containing the transistors and other active and passive components. Back-end manufacturing refers to cutting or singulating the finished wafer into the individual die and then packaging the die for structural support and environmental isolation.

One goal of semiconductor manufacturing is to produce a package suitable for faster, reliable; smaller, and higher-density integrated circuits (IC) at lower cost. Flip chip packages or wafer level packages (WLP) are ideally suited for ICs demanding high speed, high density, and greater pin count. Flip chip style packaging involves mounting the active side of the die facedown toward a chip carrier substrate or printed circuit board (PCB). The electrical and mechanical interconnect between the active devices on the die and conduction tracks on the carrier substrate is achieved through a solder bump structure comprising a large number of conductive solder bumps or balls. The solder bumps are formed by a reflow process applied to solder material deposited on metal contact pads which are disposed on the semiconductor substrate. The solder bumps are then soldered to the carrier substrate. The flip chip semiconductor package provides a short electrical conduction path from the active devices on the die to the carrier substrate in order to reduce signal propagation, lower capacitance, and achieve overall better circuit performance.

FIG. 1 illustrates a portion of flip chip 10 with a rounded or circular solder bump 12 metallurgically connected to a metal contact pad 14. A circular solder mask opening 16 is formed over substrate 18 to expose trace line 20. Trace line 20 can have a rounded pad 22 formed along a conductor 24 as shown in FIG. 2a, or a straight conductor 26 as per FIG. 2b. The solder resist opening 16 is circular in shape and made with as small or fine pitch as possible to increase routing density. The size of trace line or pad is typically made smaller than the solder resist opening 16, as seen in FIGS. 2a and 2b. As the solder bump 12 wets to trace line 20, the bump collapses and contacts the edges of the solder resist material, a phenomenon commonly known as solder resist shut-off. Since the solder bump has essentially the same rounded or circular shape as the solder resist opening, the solder bump contacts substantially the entire circumference of the solder resist opening. The solder bump stops collapsing but at this point has effectively sealed off the solder resist opening, making regions 28 inaccessible to underfill resin 29, as shown in FIG. 1. When underfill resin 29 is deposited, it cannot flow pass solder bump 12 into region 28. The region 28 develops voids under the solder bump which causes reliability problems especially when the semiconductor device is exposed to moisture and/or elevated cyclical temperatures.

### SUMMARY OF THE INVENTION

A need exists to connect solder bumps to trace lines without forming voids under the solder bumps. Accordingly, in one embodiment, the present invention is a method of packaging a semiconductor device comprising the steps of providing a semiconductor die having a contact pad, forming a rounded solder bump on the contact pad, providing a substrate having a trace line, disposing a rectangular solder resist opening over the trace line, placing the solder bump in proximity to the trace line, reflowing the solder bump to metallurgically connect the rounded solder bump to the trace line. The rounded solder bump contacts less than an entire perimeter of the rectangular solder resist opening which creates one or more vents in areas where the rounded solder bump is discontinuous with the rectangular solder resist opening. The method further includes the step of depositing underfill material under the first substrate. The underfill material penetrates through the vents to fill an area under the solder bump.

In another embodiment, the present invention is a method of packaging a semiconductor device comprising the steps of providing a first substrate or electronic device having a contact pad, forming a circular solder bump on the contact pad, providing a second substrate having a trace line, disposing a non-circular solder resist opening over the trace line, placing the solder bump in proximity to the trace line, and reflowing the circular solder bump to metallurgically connect the circular solder bump to the trace line. The circular solder bump contacts less than an entire perimeter of the non-circular solder resist opening which creates one or more vents in areas where the circular solder bump is discontinuous with the non-circular solder resist opening. The method further includes the step of depositing underfill material under the first substrate. The underfill material penetrates through the vents to fill an area under the solder bump.

In another embodiment, the present invention is a method of packaging a semiconductor device comprising the steps of providing a first substrate or electronic device having a contact pad, forming a solder bump on the contact pad, providing a second substrate having a trace line, and disposing a solder resist opening over the trace line. The solder resist opening has a shape which is mismatched to a shape of the solder bump. The method further includes the steps of placing the solder bump in proximity to the trace line, and reflowing the solder bump to metallurgically connect the solder bump to the trace line. The solder bump contacts less than an entire perimeter of the solder resist opening which creates one or more vents in areas where the solder bump is discontinuous with the solder resist opening. The method further includes the step depositing underfill material under the first substrate. The underfill material penetrates through the vents to fill an area under the solder bump.

In another embodiment, the present invention is a semiconductor package comprising a first substrate having a contact pad, a circular solder bump formed on the contact pad, and a second substrate having a trace line. The solder bump is metallurgically connected to the trace line. A non-circular solder resist opening is formed over the trace line. The circular solder bump contacts less than an entire perimeter of the non-circular solder resist opening which creates one or more vents in areas where the circular solder bump is discontinuous with the non-circular solder resist opening. An underfill material is disposed under the first substrate. The underfill material penetrates through the vents to fill an area under the circular solder bump.

### BRIEF DESCRIPTION OF THE DRAWINGS

FIG. 1 is a conventional solder bump on a flip chip interconnected to a trace line on a substrate;

FIGS. 2a-2b illustrate a conventional trace line arrangement through a circular solder resist opening;

FIG. 3 is a flip chip semiconductor device with bumps providing electrical interconnect between an active area of the die and a chip carrier substrate;

FIG. 4 illustrates a circular solder bump on a flip chip interconnected to a trace line on a substrate through a non-circular solder resist opening;

FIGS. 5a-5c illustrate a trace line exposed through a rectangular solder resist opening; and

FIGS. 6a-6e illustrate alternate shapes for the non-circular solder resist opening.

### DETAILED DESCRIPTION OF THE DRAWINGS

The present invention is described in one or more embodiments in the following description with reference to the Figures, in which like numerals represent the same or similar elements. While the invention is described in terms of the best mode for achieving the invention's objectives, it will be appreciated by those skilled in the art that it is intended to cover alternatives, modifications, and equivalents as may be included within the spirit and scope of the invention as defined by the appended claims and their equivalents as supported by the following disclosure and drawings.

The manufacture of semiconductor devices involves formation of a wafer having a plurality of die. Each die contains hundreds or thousands of transistors and other active and passive devices performing one or more electrical functions. For a given wafer, each die from the wafer typically performs the same electrical function. Front-end manufacturing generally refers to formation of the semiconductor devices on the wafer. The finished wafer has an active side containing the transistors and other active and passive components. Back-end manufacturing refers to cutting or singulating the finished wafer into the individual die and then packaging the die for structural support and/or environmental isolation.

A semiconductor wafer generally includes an active surface having semiconductor devices disposed thereon, and a backside surface formed with bulk semiconductor material, e.g., silicon. The active side surface contains a plurality of semiconductor die. The active surface is formed by a variety of semiconductor processes, including layering, patterning, doping, and heat treatment. In the layering process, semiconductor materials are grown or deposited on the substrate by techniques involving thermal oxidation, nitridation, chemical vapor deposition, evaporation, and sputtering. Photolithography involves the masking of areas of the surface and etching away undesired material to form specific structures. The doping process injects concentrations of dopant material by thermal diffusion or ion implantation.

Flip chip semiconductor packages and wafer level packages (WLP) are commonly used with integrated circuits (ICs) demanding high speed, high density, and greater pin count. Flip chip style semiconductor device 20 involves mounting an active area 22 of die 24 facedown toward a chip carrier substrate or printed circuit board (PCB) 26, as shown in FIG. 3. Active area 22 contains active and passive devices, conductive layers, and dielectric layers according to the electrical design of the die. The electrical and mechanical interconnect is achieved through a solder bump structure 30 comprising a large number of individual conductive solder bumps or balls 32. The solder bumps are formed on bump pads or interconnect sites 34, which are disposed on active area 22. The bump pads 34 connect to the active circuits by conduction tracks in active area 22. The solder bumps 32 are electrically and mechanically connected to contact pads or interconnect sites 36 on carrier substrate 26 by a solder reflow process. The flip chip semiconductor device provides a short electrical conduction path from the active devices on die 24 to conduction tracks on carrier substrate 26 in order to reduce signal propagation, lower capacitance, and achieve overall better circuit performance.

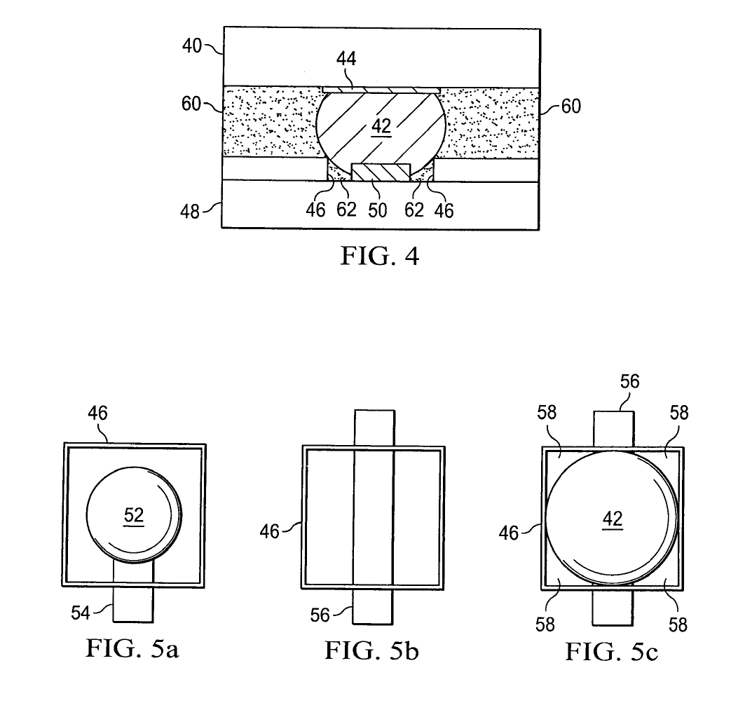

FIG. 4 illustrates a portion of flip chip 40 with a solder bump 42 metallurgically connected to a metal contact pad 44. A solder mask opening 46 is disposed over substrate 48 to expose trace line 50. Trace line 50 can have a rounded pad 52 formed along a straight conductor 54 as shown in FIG. 5a, or a straight conductor 56 as per FIG. 5b. The solder resist opening is made non-circular in shape. In one embodiment, solder resist opening 46 is made rectangular in shape as shown in FIG. 5a-5b. The rectangular solder resist opening is approximately equal in width to the solder bump, for example 90 microns.

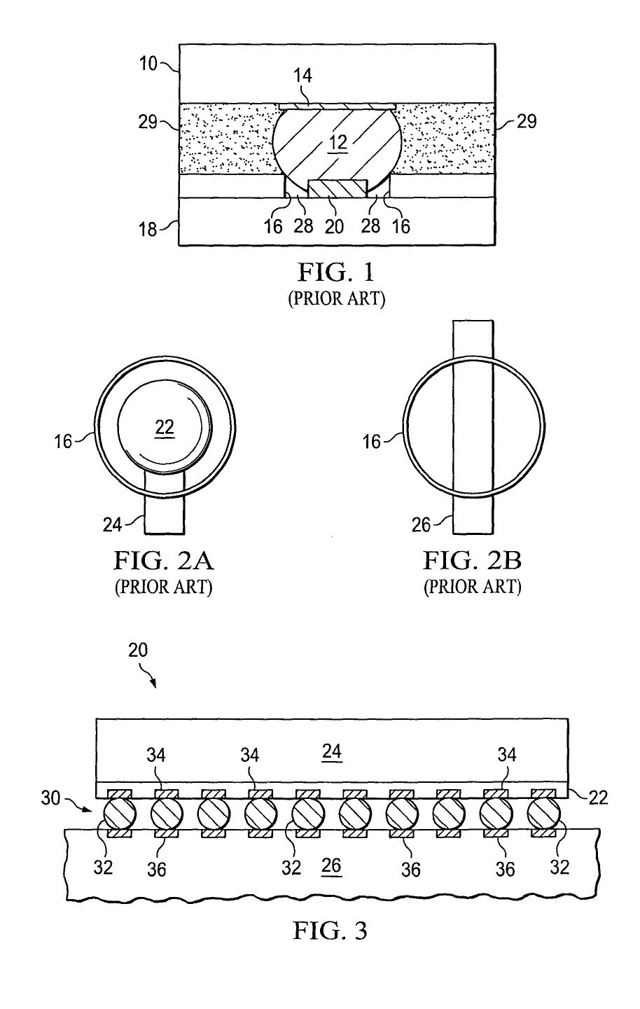

The solder bump 42 is wetted to trace line 50 in the non-circular solder resist opening 46. In most if not all cases, solder bump 42 is rounded or circular. Since the solder resist opening has a shape which is mismatched to the shape of the solder bump, the solder bump is discontinuous in at least some areas around the circumference of the solder resist opening, i.e., similar to the analogy that a round peg cannot completely fill a square hole. The non-circular shape of solder resist opening 46 prevents the rounded solder bump from sealing off all edges around the circumference of the solder resist opening. In other words, the non-circular shape of the solder resist opening creates access points or vents 58 at the four corners of solder resist opening 46 where the solder bump does not contact the solder resist opening, see FIG. 5c. The collapsing solder bump cannot physically seal off all edges of the solder resist opening because its shape does not conform to the rounded shape of the solder bump. When underfill resin 60 is applied, the resin penetrates vents 58 and fills regions 62 under the solder bump. The regions 62 are void-free which improves reliability especially if the semiconductor device is exposed to moisture and/or elevated cyclical temperatures. In order to maintain trace routing density, the width of the non-circular solder resist opening 46 is made equal to or less than the diameter of solder resist opening 16 as discussed in FIG. 1.

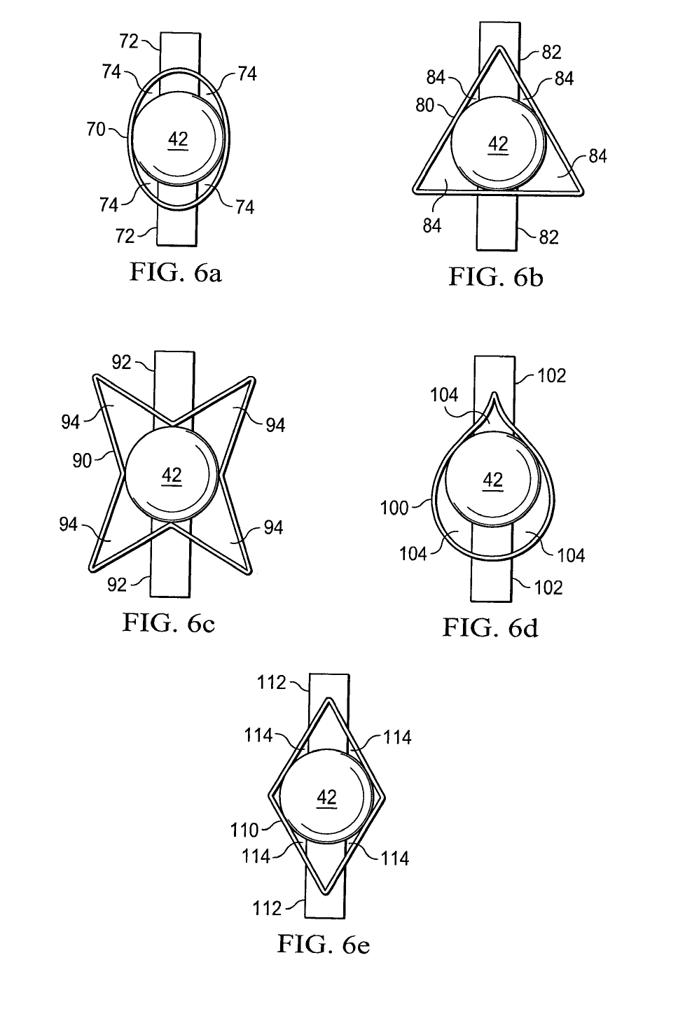

In other embodiments, other non-circular solder resist openings are shown in FIGS. 6a-6e. FIG. 6a shows an elliptical or oval-shaped solder resist opening 70 exposing trace line 72 and creating one or more vents 74. FIG. 6b shows a triangle-shaped solder resist opening 80 exposing trace line 82 and creating one or more vents 84. FIG. 6c shows a star-shaped solder resist opening 90 exposing trace line 92 and creating one or more vents 94. FIG. 6d shows a tear-drop shaped solder resist opening 100 exposing trace line 102 and creating one or more vents 104. FIG. 6e shows a diamond-shaped solder resist opening 110 exposing trace line 112 and creating one or more vents 114. In each case, the non-circular shape of the solder resist opening creates access points or vents as shown. The collapsing solder bump cannot physically seal off all edges of the solder resist opening because its shape does not conform to the typical rounded shape of the solder bump. The rounded solder bump contacts less than an entire perimeter of the rectangular solder resist opening and creates one or more vents in areas where the rounded solder bump is discontinuous with the shape of the solder resist opening. When underfill resin 60 is applied, the resin 60 penetrates the vents and fills regions 62 under the solder bump. The regions 62 are void-free which improves reliability especially the semiconductor device is exposed to moisture. Practically any shape for the solder resist opening other than the shape of the solder bump, i.e., circular, will create the necessary vents to allow the underfill material to press past the solder bump and fill in the void under the bump. The intersecting or adjoining straight edges may be chamfered or rounded as shown in 6b-6e.

In the case where solder bump 42 is not rounded or circular, solder resist opening 46 is made of a shape that is mismatched to the shape of the solder bump. The mismatch in shapes will create discontinuities around the circumference between the solder bump and solder resist opening. The non-matching shapes between the solder resist opening and solder bumps create vents which allow underfill resin 60 to penetrate past the bump and fill any gap formed under the bump.

While one or more embodiments of the present invention have been illustrated in detail, the skilled artisan will appreciate that modifications and adaptations to those embodiments may be made without departing from the scope of the present invention as set forth in the following claims.

1-25. (canceled)

26. A method of making a semiconductor device, comprising:
providing a semiconductor die having a contact pad;
forming a rounded bump on the contact pad;
providing a substrate having a trace line;
forming a rectangular solder resist opening over the trace line, the rectangular solder resist opening having a width substantially equal to a diameter of the rounded bump;
placing the rounded bump in proximity to the trace line;
reflowing the bump to metallurgically connect the bump to the trace line, wherein the rounded bump contacts less than an entire perimeter of the rectangular solder resist opening which creates vents in areas where the rounded bump is discontinuous with the rectangular solder resist opening; and
depositing underfill material under the semiconductor die, the underfill material penetrating through the vents to fill an area under the rounded bump to be void-free.

27. The method of claim 26, wherein the trace line is a straight conductor.

28. The method of claim 26, wherein the trace line includes a rounded contact pad.

29. The method of claim 26, wherein the rectangular solder resist opening creates vents at each corner where the rounded bump is discontinuous with the solder resist.

30. The method of claim 26, wherein intersecting edges of the rectangular solder resist opening are chamfered or rounded.

31. A method of making a semiconductor device, comprising:
providing a first substrate having a contact pad;
forming a circular bump on the contact pad;
providing a second substrate having a trace line;
disposing a non-circular solder resist opening over the trace line;
placing the circular bump in proximity to the trace line;
reflowing the bump to metallurgically connect the bump to the trace line, wherein the circular bump contacts less than an entire perimeter of the non-circular solder resist opening which creates vents in areas where the circular bump is discontinuous with the non-circular solder resist opening; and
depositing underfill material under the first substrate, the underfill material penetrating through the vents to fill an area under the circular bump to be void-free.

32. The method of claim 31, wherein the first substrate is part of a semiconductor die.

33. The method of claim 31, wherein the non-circular solder resist opening has a shape selected from the group of a rectangle, triangle, ellipse, oval, star, and tear-drop.

34. The method of claim 31, wherein the trace line is a straight conductor.

35. The method of claim 31, wherein the trace line includes a rounded contact pad.

36. The method of claim 31, wherein the non-circular solder resist opening is approximately equal to a width of the circular bump.

37. A method of making a semiconductor device, comprising:
providing a first substrate having a contact pad;
forming a bump on the contact pad;
providing a second substrate having a trace line;
disposing a solder resist opening over the trace line, the solder resist opening having a shape which is mismatched to a shape of the bump;
placing the bump in proximity to the trace line;
reflowing the bump to metallurgically connect the bump to the trace line, wherein the bump contacts less than an entire perimeter of the solder resist opening which creates vents in areas where the bump is discontinuous with the solder resist opening; and
depositing underfill material under the first substrate, the underfill material penetrating through the vents to fill an area under the bump to be void-free.

38. The method of claim 37, wherein the first substrate is part of a semiconductor die.

39. The method of claim 37, wherein the bump is circular.

40. The method of claim 37, wherein the solder resist opening is non-circular.

41. The method of claim 37, wherein the solder resist opening has a shape selected from the group of a rectangle, triangle, ellipse, oval, star, and tear-drop.

42. The method of claim 37, wherein the trace line is a straight conductor.

43. The method of claim 37, wherein the trace line includes a rounded contact pad.

44. The method of claim 37, wherein the rectangular solder resist opening is approximately equal to a width of the bump.

45. A semiconductor device, comprising:
a first substrate having a contact pad;
a circular bump formed on the contact pad;
a second substrate having a trace line, the circular bump being metallurgically connected to the trace line;
a non-circular solder resist opening formed over the trace line, wherein the circular bump contacts less than an entire perimeter of the non-circular solder resist opening which creates vents in areas where the circular bump is discontinuous with the non-circular solder resist opening; and
an underfill material disposed under the first substrate, the underfill material penetrating through the vents to fill an area under the circular bump to be void-free.

46. The semiconductor device of claim 45, wherein the first substrate is part of a semiconductor die.

47. The semiconductor device of claim 45, wherein the non-circular solder resist opening has a shape selected from the group of a rectangle, triangle, ellipse, oval, star, and tear-drop.

48. The semiconductor device of claim 45, wherein the trace line is a straight conductor.

49. The semiconductor device of claim 45, wherein the trace line includes a rounded contact pad.

50. The semiconductor device of claim 45, wherein the rectangular solder resist opening is approximately equal to a width of the circular bump.
